(19) United States
(12) Patent Application Publication
(10) Pub. No.: US 2025/0349720 A1
(43) Pub. Date: Nov. 13, 2025

(54) INTERCONNECTION STRUCTURE AND METHODS OF FORMING THE SAME

(71) Applicant: TAIWAN SEMICONDUCTOR MANUFACTURING COMPANY, LTD., Hsinchu (TW)

(72) Inventors: Pei-Yu CHOU, Hsinchu (TW); Yu-Lien HUANG, Hsinchu (TW); Tze-Liang LEE, Hsinchu (TW)

(21) Appl. No.: 19/274,722

(22) Filed: Jul. 21, 2025

Related U.S. Application Data
(62) Division of application No. 17/722,386, filed on Apr. 18, 2022.

(51) Int. Cl. H01L 23/532; H01L 21/768; H01L 23/522

(52) U.S. Cl. CPC H01L 23/53295; H01L 21/76832; H01L 23/5226

(57) ABSTRACT

A method for forming an interconnection structure is provided. The method includes forming a first conductive feature in a first dielectric material, forming an etch stop layer over the first dielectric material, which includes forming a boron-containing layer, and forming an oxygen-rich boron oxide layer on the boron-containing layer. The method also includes forming a second dielectric material over the etch stop layer, forming an opening through the second dielectric material and the etch stop layer to expose a top surface of the first conductive feature, and forming a second conductive feature in the opening.

### CROSS-REFERENCE TO RELATED APPLICATIONS

This application is a divisional application of U.S. patent application Ser. No. 17/722,386 filed Apr. 18, 2022, which is incorporated by reference in its entirety.

### BACKGROUND

As the semiconductor industry introduces new generations of integrated circuits (IC) having higher performance and more functionality, the density of the elements forming the ICs increases, while the dimensions, sizes and spacing between components or elements are reduced. However, device geometries having smaller dimensions created new limiting factors. Particularly, challenge of preventing undesirable electrical shorts between a contact structure and adjacent conductive structures becomes more complex when multiple exposure and etch processes are employed to form contact features. Therefore, there exists a need to provide a reliable and electrical-short-proof method of forming contact structures for integrated semiconductor device structures.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective sectional view of a semiconductor device structure, in accordance with some embodiments.

FIG. 2 is a cross-sectional side view of a stage of manufacturing the semiconductor device structure, in accordance with some embodiments.

FIGS. 3A-3J are cross-sectional side views of various stages of manufacturing the interconnection structure, in accordance with some embodiments.

FIGS. 3B-1 to 3B-6 are exemplary structures showing a portion of the first etch stop layer of FIG. 3B, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

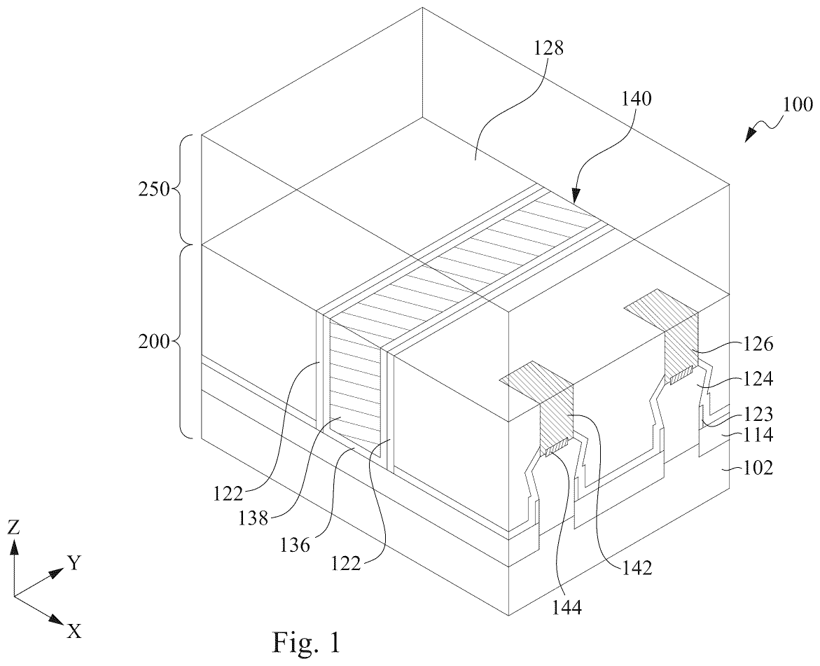

FIG. 1 is a perspective sectional view of a semiconductor device structure 100 including a device layer 200 and an interconnection structure 250, in accordance with some embodiments. The device layer 200 includes a substrate 102 and one or more devices formed in or on the substrate 102. The substrate 102 may be a semiconductor substrate. In some embodiments, the substrate 102 includes a single crystalline semiconductor layer on at least the surface of the substrate 102. The substrate 102 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb), and indium phosphide (InP). For example, the substrate 102 is made of Si. In some embodiments, the substrate 102 is a silicon-on-insulator (SOI) substrate, which includes an insulating layer (not shown) disposed between two silicon layers. In one aspect, the insulating layer is an oxygen-containing material, such as an oxide.

The substrate 102 may include various regions that have been suitably doped with impurities (e.g., p-type or n-type impurities). The dopants are, for example phosphorus for an n-type fin field effect transistor (FinFET) and boron for a p-type FinFET.

As described above, the device layer 200 may include any suitable devices, such as transistors, diodes, imaging sensors, resistors, capacitors, inductors, memory cells, or a combination thereof. In some embodiments, the device layer 200 includes transistors, such as planar field effect transistors (FETs), FinFETs, nanostructure transistors, or other suitable transistors. The nanostructure transistors may include nanosheet transistors, nanowire transistors, gate-all-around (GAA) transistors, multi-bridge channel (MBC) transistors, or any transistors having the gate electrode surrounding the channels. An example of the device formed on the substrate 102 is a FinFET, which is shown in FIG. 1. The device layer 200 includes source/drain (S/D) features 124 and gate stacks 140 (only one is shown in FIG. 1). Each gate stack 140 may be disposed between S/D features 124 serving as source regions and S/D features 124 serving as drain regions. For example, each gate stack 140 may extend along the Y-axis between one or more S/D features 124 serving as source regions and one or more S/D features 124 serving as drain regions. While not shown, channel regions are formed between the S/D features 124 and have at least three surfaces wrapped around by the gate stack 140.

The S/D features 124 may include a semiconductor material, such as Si or Ge, a III-V compound semiconductor, a II-VI compound semiconductor, or other suitable semiconductor material. Exemplary S/D feature 124 may include, but are not limited to, Ge, SiGe, GaAs, AlGaAs, GaAsP, SiP, InAs, AlAs, InP, GaN, InGaAs, InAlAs, GaSb, AlP, GaP, and the like. The S/D features 124 may include p-type dopants, such as boron; n-type dopants, such as phosphorus or arsenic; and/or other suitable dopants including combinations thereof. The S/D features 124 may be formed by an epitaxial growth method using CVD, atomic layer deposition (ALD) or molecular beam epitaxy (MBE). The channel regions may include one or more semiconductor materials, such as Si, Ge, GeSn, SiGe, GaAs, InSb, GaP, GaSb, InAlAs, InGaAs, GaSbP, GaAsSb, GaN, GaP, or InP. The channel regions may include the same semiconductor material as the substrate 102. In some embodiments, the device layer 200 may include FinFETs, and the channel regions are a plurality of fins disposed below the gate stacks 140. In some embodiments, the device layer 200 may include nanostructure transistors, and the channel regions are surrounded by the gate stacks 140.

The gate stack 140 includes a gate electrode layer 138 disposed over the channel region (or surrounding the channel region for nanostructure transistors). The gate electrode layer 138 may be a metal-containing material such as tungsten, cobalt, aluminum, ruthenium, copper, multilayers thereof, or the like, and can be deposited by ALD, plasma enhanced chemical vapor deposition (PECVD), MBD, physical vapor deposition (PVD), or any suitable deposition technique. The gate stack 140 may further include a gate dielectric layer 136 disposed over the channel region. The gate electrode layer 138 may be disposed over the gate dielectric layer 136. In some embodiments, an interfacial layer (not shown) may be disposed between the channel region and the gate dielectric layer 136, and one or more work function layers (not shown) may be formed between the gate dielectric layer 136 and the gate electrode layer 138. The interfacial layer may include a dielectric material, such as an oxygen-containing material or a nitrogen-containing material, or multilayers thereof, and may be formed by any suitable deposition method, such as CVD, PECVD, or ALD. The gate dielectric layer 136 may include a dielectric material such as an oxygen-containing material or a nitrogen-containing material, a high-k dielectric material having a k value greater than that of silicon dioxide, or multilayers thereof. The gate dielectric layer 136 may be formed by any suitable method, such as CVD, PECVD, or ALD. In some embodiments, the gate dielectric layer 136 may be a conformal layer. The term “conformal” may be used herein for ease of description upon a layer having substantial same thickness over various regions. The one or more work function layers may include aluminum titanium carbide, aluminum titanium oxide, aluminum titanium nitride, or the like.

Gate spacers 122 are formed along sidewalls of the gate stacks 140 (e.g., sidewalls of the gate dielectric layer 136). The gate spacers 122 may include silicon oxycarbide, silicon nitride, silicon oxynitride, silicon carbon nitride, the like, multi-layers thereof, or a combination thereof, and may be deposited by CVD, ALD, or other suitable deposition technique. In some embodiments, fin sidewall spacers 123 may be disposed on opposite sides of each S/D feature 124, and the fin sidewall spacers 123 may include the same material as the gate spacers 122. Portions of the gate stacks 140, the gate spacers 122, and the fin sidewall spacers 123 may be disposed on isolation regions 114. The isolation regions 114 are disposed on the substrate 102. The isolation regions 114 may include an insulating material such as an oxygen-containing material, a nitrogen-containing material, or a combination thereof. In some embodiments, the isolation regions 114 are shallow trench isolation (STI). The insulating material may be formed by a high-density plasma chemical vapor deposition (HDP-CVD), a flowable chemical vapor deposition (FCVD), or other suitable deposition process. In one aspect, the isolation regions 114 includes silicon oxide that is formed by a FCVD process.

A contact etch stop layer (CESL) 126 is formed on the S/D features 124 and the isolation region 114, and an interlayer dielectric (ILD) layer 128 is formed on the CESL 126. The CESL 126 can provide a mechanism to stop an etch process when forming openings in the ILD layer 128. The CESL 126 may be conformally deposited on surfaces of the S/D features 124 and the isolation regions 114. The CESL 126 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be deposited by CVD, PECVD, ALD, or any suitable deposition technique. The ILD layer 128 may include an oxide formed by tetraethylorthosilicate (TEOS), un-doped silicate glass, or doped silicon oxide such as borophosphosilicate glass (BPSG), fused silica glass (FSG), phosphosilicate glass (PSG), boron doped silicon glass (BSG), organosilicate glass (OSG), SiOC, and/or any suitable low-k dielectric materials (e.g., a material having a dielectric constant lower than that of silicon dioxide), and may be deposited by spin-on, CVD, FCVD, PECVD, PVD, or any suitable deposition technique.

The S/D contacts 142 may be disposed in the ILD layer 128 and over the S/D feature 124. The S/D contacts 142 may be electrically conductive and include a material having one or more of Ru, Mo, Co, Ni. W, Ti, Ta, Cu, Al, TiN or TaN, and the S/D contacts 142 may be formed by any suitable method, such as electro-chemical plating (ECP), or PVD. A silicide layer 144 may be disposed between the S/D contacts 142 and the S/D feature 124. The silicide layers 144 may be made of a metal or metal alloy silicide, and the metal includes a noble metal, a refractory metal, a rare earth metal, alloys thereof, or combinations thereof.

In integrated circuits, interconnection structures (or interconnect structures) are used to provide signal routing and power supply to semiconductor devices. An integrated circuit chip typically includes a device layer, fabricated during front-end-of-line (FEOL) and middle-of-line (MOL) processes, and a back-end-of-line (BEOL) layer. The device layer may be formed in and/or on the substrate, and the BEOL layer is formed on a front side and/or backside of the device layer. The device layer may include various semiconductor devices, such as transistors, diodes, capacitors, resistors, etc., and may be formed in and/or on the substrate. In some embodiments, the device layer may also include the MOL structures, such as one or more dielectric layers with conductive features connected to gates and source/drain features in the device layer. Interconnection structures typically include conductive lines and vias formed in both the device layer and the BEOL layers.

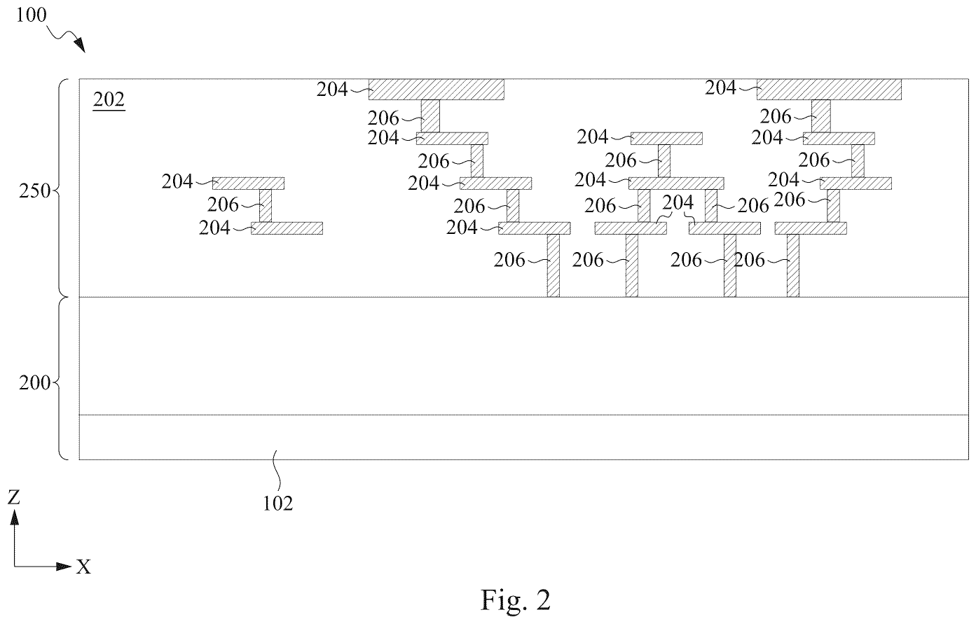

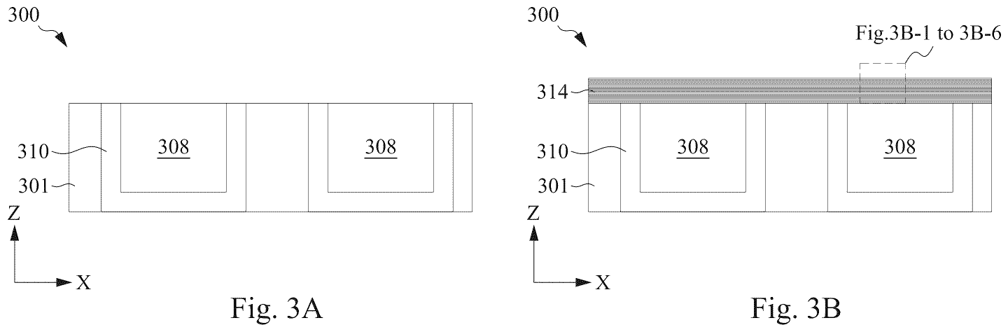

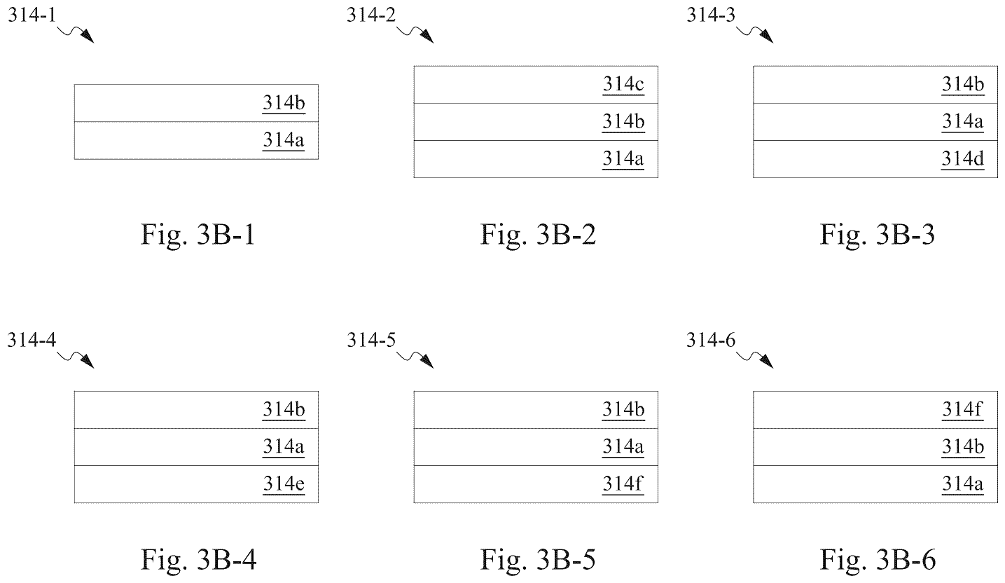

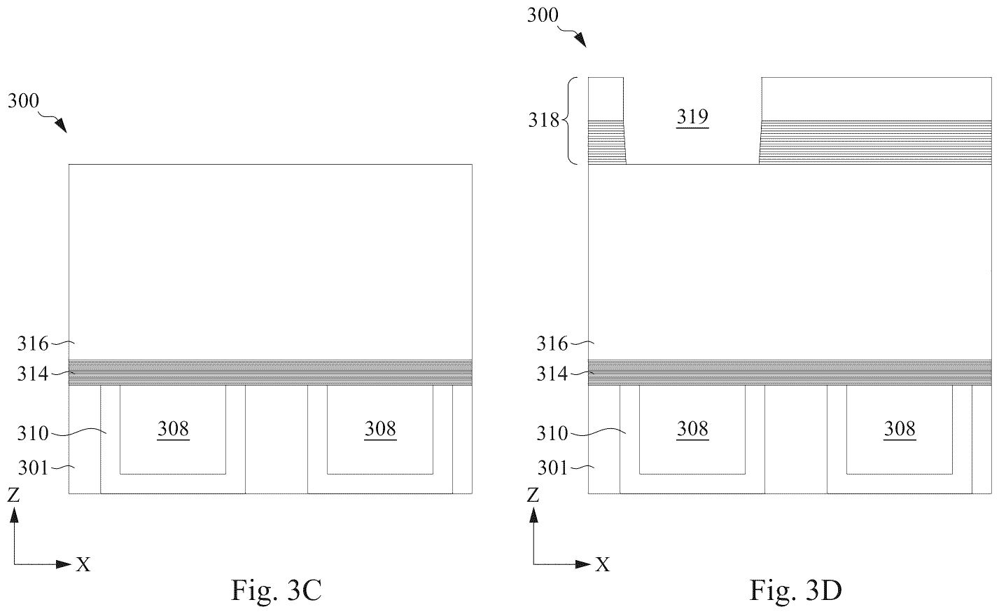

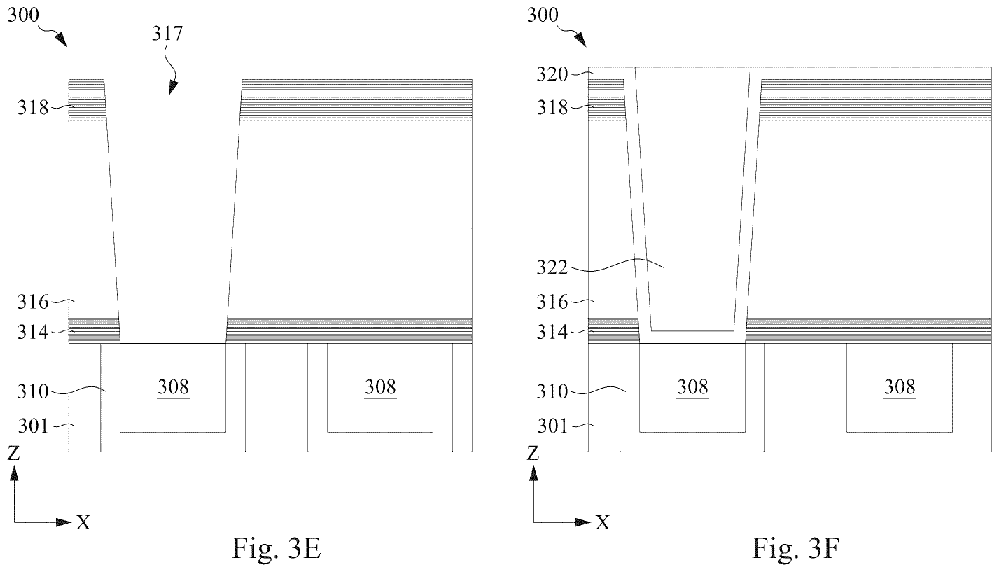

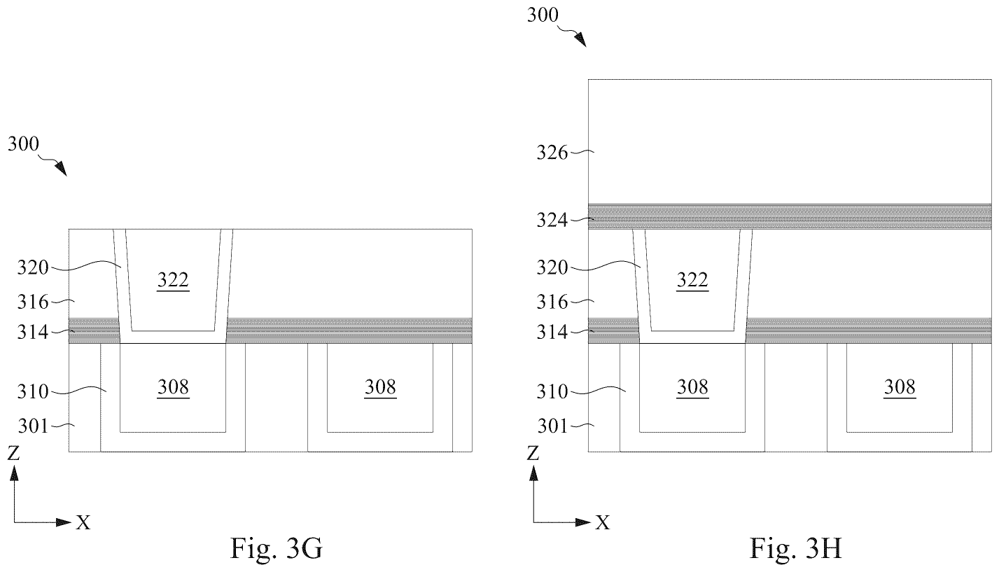

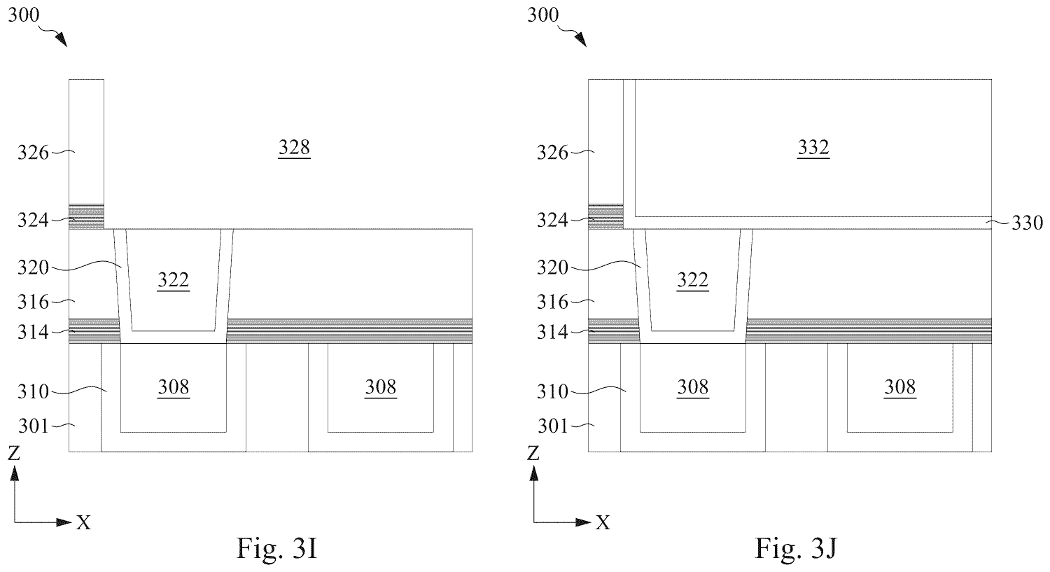

FIG. 2 is a cross-sectional side view of a stage of manufacturing the semiconductor device structure 100, in accordance with some embodiments. The interconnection structure 250 is formed over the device layer 200. The interconnection structure 250 includes various conductive features, such as conductive lines 204 and conductive vias 206, formed in a dielectric layer 202. The dielectric layer 202 may be an intermetal dielectric (IMD) layer or an interlayer dielectric (ILD) layer. The dielectric layer 202 may include multiple dielectric layers embedding multiple levels of conductive lines and vias 204, 206. The dielectric layer 202 is made from a dielectric material, such as SiOₓ, SiOₓC_{y}Hz, or SiOₓC_{y}, where x, y and z are integers or non-integers. In some embodiments, the dielectric layer 202 includes a low-k dielectric material having a k value less than that of silicon oxide. The conductive lines 204 and conductive vias 206 may be made from one or more electrically conductive materials, such as metal, metal alloy, metal nitride, or silicide. The conductive vias 206 and lines 204 are arranged in levels to provide electrical paths to the gate electrode 138 (FIG. 1) and S/D contacts 142 (FIG. 1) in the device layer 200. In some embodiments, a backside interconnection structure (not shown), similar to the interconnection structure 250, may be formed on the backside of the device layer 200 to provide power supply and/or additional signal connection to the device layer 200. FIGS. 3A-3J to be discussed below relate to various embodiments of interconnection structures and methods to form thereof according to the present disclosure.

FIGS. 3A-3J are cross-sectional side views of various stages of manufacturing the interconnection structure 300, in accordance with some embodiments. Various embodiments of the interconnection structure 300 may be used to form one or more layers of the interconnection structure 250 shown in FIGS. 1 and 2. In FIG. 3A, the interconnection structure 300 includes a dielectric material 301, which may be an ILD layer or an IMD layer. For example, the dielectric material 301 may be the ILD layer 128 (FIG. 1) or the dielectric layer 202 (FIG. 2). The dielectric material 301 may include the same material as the ILD layer 128 or the dielectric layer 202. In some embodiments, the dielectric material 301 includes a low-k dielectric material, such as SiOCH. The dielectric material 301 may be formed by CVD, FCVD, ALD, spin coating, or other suitable process. The interconnection structure 300 may include one or more conductive features 308 disposed in the dielectric material 301. The one or more conductive features 308 may be electrically connected to the S/D features 124 (FIG. 1) and/or the gate electrode layer 138 (FIG. 1). In some embodiments, the conductive features 308 are the conductive lines 204 or conductive vias 206 shown in FIG. 2. The conductive feature 308 may include an electrically conductive material, such as Cu, Co, W, Ru, Mo, Zn, alloys thereof, or combinations thereof, and may be formed by any suitable process, such as PVD.

In some embodiments, a barrier layer 310 may be formed between the dielectric material 301 and the conductive feature 308. While not shown, a liner may be formed between the barrier layer 310 and the conductive feature 308. The barrier layer 310 may include metal nitride, metal oxide, two-dimensional (2D) material, or a combination thereof. Suitable metals for the barrier layer 310 may include, but are not limited to, Ta, Ti, W, Mn, Zn, In, or Hf. In some embodiments, the barrier layer 310 is a metal nitride, such as TaNₓ, TiNₓ or WNₓ, or a metal oxide, such as HfOₓ. The term “2D material” used in this disclosure refers to single layer material or monolayer-type material that is atomically thin crystalline solid having intralayer covalent bonding and interlayer van der Waals bonding. Examples of a 2D material may include graphene, hexagonal boron nitride (h-BN), or transition metal dichalcogenides (MX₂), where M is a transition metal element and X is a chalcogenide element. Some exemplary MX₂ materials may include, but are not limited to Te₂, WS₂, MoS₂, WSe₂, MoSe₂, or any combination thereof. The barrier layer 310 may prevent the metal diffusion from the conductive feature 308 to the dielectric material 301. In some embodiments, the conductive feature 308 includes a metal that is not susceptible to diffusion, and the barrier layer 310 may be omitted. The liner (if used) may include Co, Ru, Mn, Zn, Zr, W, Mo, Os, Ir, Al, Fe, Ni, alloys thereof, or combinations thereof. In some embodiments, the liner is Co or Ru. In some embodiments, the liner is CoRu. In some embodiments, the liner may include the same material as the conductive feature 308. The barrier layer 310 and the liner (if used) may each have a thickness ranging from about 3 Angstroms to about 100 Angstroms.

In FIG. 3B, a first etch stop layer 314 is formed over the dielectric material 301. In some embodiments, the first etch stop layer 314 is in contact with the dielectric material 301, the conductive features 308, and the barrier layer 310. The first etch stop layer 314 may include a material chemically different from the dielectric material 301 in order to provide etch selectivity with respect to the dielectric material 301. The first etch stop layer 314 may be a single layer or a multi-layer structure.

In some embodiments, the first etch stop layer 314 may include silicon nitride, silicon carbide, oxygen-doped silicon carbide (ODC), silicon carbon nitride, silicon oxynitride, carbon nitride, silicon oxide, silicon carbon oxide, aluminum oxide, or the like, or any combination thereof. In some embodiments, the first etch stop layer 314 may include two or more layers of dielectric material discussed herein. For example, the first etch stop layer 314 may include a first layer in contact with the dielectric material 301, a second layer disposed on the first layer, a third layer disposed on the second layer, and a fourth layer disposed on the third layer. In some embodiments, the first, second, third, and fourth layers may include the same dielectric material but with different concentration ratio, composition, and/or oxidation rates. In some embodiments, the first and third layers may include the same dielectric material but with different concentration ratio, composition, and/or oxidation rates and the second and fourth layers may include the same dielectric material but with different concentration ratio, composition, and/or oxidation rates. For example, the first layer may include aluminum oxide, the second layer may include oxygen-doped silicon carbide, the third layer may include aluminum oxide, and the fourth layer may include oxygen-doped silicon carbide. The first etch stop layer 314 may be formed by any suitable process, such as CVD, ALD, PVD, PEALD, or PECVD.

In some embodiments, the first etch stop layer 314 includes a boron-based layer, an oxygen-rich boron oxide (BOₓ) layer, or a combination thereof. The boron-based layer provides better etch selectivity with respect to the dielectric material 301. The oxygen-rich BOₓ layer may serve as a buffer layer to enhance the etch selectivity of the boron-based layer with respect to the dielectric material 301. The oxygen-rich BOₓ layer may be disposed above or below the boron-based layer to improve adhesion between the boron-based layer and a layer adjacent to the boron-based layer. In some embodiments, the first etch stop layer 314 includes a boron-based layer, an oxygen-rich BOₓ layer, a boron-free layer, or any combination thereof. Likewise, the boron-free layer can be used to enhance the etch selectivity of the boron-based layer with respect to the dielectric material 301. In some embodiments, the boron-based layer may have a first atomic percentage of boron and the oxygen-rich BOₓ layer may have a second atomic percentage of boron that is greater than the first atomic percentage of boron. In any case, each layer in the first etch stop layer 314 may have a thickness ranging from about 1 nm to about 50 nm. In some embodiments, the boron-based layer and/or boron-free layer may each have a thickness that is equal to or greater than the thickness of the oxygen-rich BOₓ layer. In one example, the oxygen-rich BOₓ layer has a thickness about 1 nm. In some embodiments, the boron-based layer or boron-free layer has a first thickness T1 and the oxygen-rich BOₓ layer has a second thickness T2, and the ratio of T1 to T2 (T1:T2) may be about 1.5:1 to about 10:1, for example about 3:1 to about 8:1.

Boron-based layers may include, but are not limited to, boron nitride (BN), boron carbide (BC), boron carbon nitride (BCN), boron oxide (BO), silicon boron nitride (SiBN), or the like, or any combination thereof. Other boron-based materials such as boron silicon nitride (BSiN), boron silicon oxide (BSiₓO_{y}), boron carbon silicon nitride (BCSiN), may also be used. The boron-based layer may be doped or undoped. In some embodiments, the boron-based layer may have a hardness higher than 10 GPa and a dielectric constant in a range between 1.0 and 4.0. In cases where boron oxide (BO) is used as the boron-based layer, the BO may have an atomic percentage of boron in a range of about 15 at % to about 45 at %.

Exemplary boron-free layers may include, but are not limited to, silicon nitride (SiN), silicon carbide (SiC), oxygen-doped silicon carbide (ODC), silicon carbon nitride (SiCN), silicon oxynitride (SiON), carbon nitride (CN), silicon oxide (SiOₓ), silicon carbon oxide (SiCO), aluminum nitride (AlN), aluminum oxide (AlOₓ), or the like, or any combination thereof. The boron-free layer may be formed by introducing any one or more of a silicon-containing precursor, a nitrogen-containing precursor (as discussed above), a carbon-containing precursor (as discussed above), and an oxygen-containing precursor into the process chamber. Suitable gases for the silicon-containing precursor may include silane (SiH₄), dimethylsilane ((CH₃)₂SiH₂), methylsilane (SiH(CH₃)₃), dichlorosilane (SiH₂Cl₂, DCS), trichlorosilane (SiHCl₃, TCS), or any suitable gases comprising Si, N, H, and optionally C in its molecule. Suitable gases for the oxygen-containing precursor may include O₂, O₃, H₂O₂, or a combination thereof.

Exemplary oxygen-rich BOₓ layers may have an atomic percentage of oxygen in a range of about 50 at % to about 80 at % and an atomic percentage of boron in a range of about 20 at % to about 50 at %. If the atomic percentage of oxygen is greater than 80 at %, the etch selectivity between the oxygen-rich BOₓ layer and a subsequent layer (e.g., a first dielectric layer 316 shown in FIG. 3C) to be formed on the oxygen-rich BOₓ layer may be reduced. On the other hand, if the atomic percentage of oxygen is less than 50 at %, the oxygen-rich BOₓ layer may have poor adhesion to a subsequent layer (e.g., a first dielectric layer 316) to be formed on the oxygen-rich BOₓ layer. Likewise, if the atomic percentage of boron is greater than 50 at %, the oxygen-rich BOₓ layer may have poor adhesion to a subsequent layer (e.g., a first dielectric layer 316) to be formed on the oxygen-rich BOₓ layer. Also, the dielectric constant (k) value of the oxygen-rich BOₓ layer may increase, which in turn affects the electrical insulation property. On the other hand, if the atomic percentage of boron is less than 20 at %, the etch selectivity between the oxygen-rich BOₓ layer and a subsequent layer (e.g., a first dielectric layer 316) to be formed on the oxygen-rich BOₓ layer may be reduced. The BOₓ layers may be formed using any suitable oxidation process, such as a surface oxidation process using moisture, a soaking process using one or more oxygen-containing precursors (e.g., O₂, O₃, N₂O, or the like, or any combination thereof), or a plasma treatment using one or more oxygen-containing precursors.

The boron-based layer may be formed by introducing any one or more of a boron-containing precursor, a nitrogen-containing precursor, and a carbon-containing precursor into a process chamber in which a semiconductor device structure (e.g., the semiconductor device structure 100 on which the interconnection structure 300 is formed) is placed. Suitable gases for the boron-containing precursor may include, but are not limited to, borane (BH₃), diborane (B₂H₆), boron trichloride (BCl₃), triethyl borate (TEB), borazine (B₃N₃H₆), or an alkyl-substituted derivative of borazine, or the like. Suitable gases for the nitrogen-containing precursor may include, but are not limited to, nitrogen (N₂), ammonia (NH₃), hydrazine (N₂H₄), nitrous oxide (N₂O), or the like, or combinations thereof. Suitable gases for the carbon-containing precursor may include, but are not limited to, methane (CH₄), ethane (C₂H₆), acetylene (C₂H₂), ethylene (C₂H₄), benzene (C₆H₆), trimethylamine (CH₃)₃N, hydrogen cyanide (HCN), or other suitable carbon-containing gas. A diluent gas, such as hydrogen (H₂) and/or argon (Ar), may be introduced into the process chamber along with one or more precursors for the boron-based layer. In various embodiments, the boron-based layer may be formed at a deposition temperature lower than 550 degrees Celsius, for example about 200 degrees Celsius to about 500 degrees Celsius, and a chamber pressure of about 0.5 Torr to about 10 Torr. The precursor gases may be introduced into the process chamber at a flow rate of about 1 Å/second to about 10 Å/second. The boron-based layer may be formed by CVD, ALD, PVD, PEALD, or PECVD, or other suitable deposition processes.

In cases where the boron-based layer is BN, the boron-containing precursor may be BH₃ or BCl₃ and the nitrogen-containing precursor may be NH₃. In one example, the boron-containing precursor is BH₃ and the nitrogen-containing precursor is NH₃. In another example, the boron-containing precursor is BCl₃ and the nitrogen-containing precursor is NH₃.

In cases where the boron-based layer is BC, the boron-containing precursor may be BCl₃ or B₂H₆ and the carbon-containing precursor may be C₂H₂ or CH₄. In one example, the boron-containing precursor is BCl₃ and the carbon-containing precursor is C₂H₂. In another example, the boron-containing precursor is B₂H₆ and the carbon-containing precursor is CH₄.

In cases where the boron-based layer is BCN, the boron-containing precursor may be BCl₃ or B₂H₆, the nitrogen-containing precursor may be NH₃, and the carbon-containing precursor may be C₂H₂ or C₂H₄. In one example, the boron-containing precursor is BCl₃, the nitrogen-containing precursor is NH₃, and the carbon-containing precursor is C₂H₂. In another example, the boron-containing precursor is B₂H₆, the nitrogen-containing precursor is NH₃, and the carbon-containing precursor is C₂H₄.

FIGS. 3B-1 to 3B-6 are exemplary structures showing a portion of the first etch stop layer 314 of FIG. 3B in accordance with some embodiments of the present disclosure. The etch stop layers 314-1 to 314-6 as shown in FIGS. 3B-1 to 3B-6 may be used to replace the first etch stop layer 314 of FIG. 3B. Depending on the application, the etch stop layers 314-1 to 314-6 may be disposed between a dielectric layer and an ILD layer or and IMD layer in an interconnection structure, such as the interconnection structure 300.

FIG. 3B-1 illustrates a cross-sectional view of a first etch stop layer 314-1 in accordance some embodiments. The first etch stop layer 314-1 is a bi-layer structure including a first layer 314a and a second layer 314b disposed on the first layer 314a. The first layer 314a may be in contact with the dielectric material 301, the conductive features 308, and the barrier layer 310. In some embodiments, the first layer 314a is a boron-based layer and the second layer 314b is an oxygen-rich BOₓ layer, all of which may be formed of the material discussed above with respect to FIG. 3B. In one exemplary embodiment, the first layer 314a is BN and the second layer 314b is an oxygen-rich BOₓ layer. In another exemplary embodiment, the first layer 314a is BC and the second layer 314b is an oxygen-rich BOₓ layer. In yet another exemplary embodiment, the first layer 314a is a BO having a first atomic percentage of oxygen and the second layer 314b is an oxygen-rich BOₓ layer having a second atomic percentage of oxygen greater than the first atomic percentage of oxygen. Having the oxygen-rich BOₓ layer formed on the boron-based layer is advantageous as it provides better adhesion between the boron-based layer and the first dielectric layer 316 (FIG. 3C) to be formed on the oxygen-rich BOₓ layer.

FIG. 3B-2 illustrates a cross-sectional view of a first etch stop layer 314-2 in accordance some embodiments. The embodiment of FIG. 3B-2 is substantial identical to the embodiment shown in FIG. 3B-1 except that the first etch stop layer 314-2 is a tri-layer structure in which a third layer 314c is disposed above and in contact with the second layer 314b. The third layer 314c may include the same material or different material as the first layer 314a. In some embodiments, the first layer 314a and the third layer 314c are boron-based layers and the second layer 314b is an oxygen-rich BOₓ layer, all of which may be formed of the material discussed above with respect to FIG. 3B. In one exemplary embodiment, the first layer 314a is BN or BC, the second layer 314b is an oxygen-rich BOₓ layer, and the third layer 314c is BN or BC.

FIG. 3B-3 illustrates a cross-sectional view of a first etch stop layer 314-3 in accordance some embodiments. The embodiment of FIG. 3B-3 is substantial identical to the embodiment shown in FIG. 3B-1 except that the first etch stop layer 314-3 is a tri-layer structure in which a third layer 314d is disposed below and in contact with the first layer 314a. In other words, the first layer 314a is disposed between and in contact with the second layer 314b and the third layer 314d. The third layer 314d may include the same material as the second layer 314b. In some embodiments, the first layer 314a may be BN or BC, and the second layer 314b and the third layer 314d are both oxygen-rich BOₓ layers. In some embodiments, the first layer 314a is a BO having a first atomic percentage of oxygen, and the second layer 314b and the third layer 314d are oxygen-rich BOₓ layers each having a second atomic percentage of oxygen greater than the first atomic percentage of oxygen. Having the oxygen-rich BOₓ layers (e.g., the second and third layers 314b, 314d) formed on and below the boron-based layer (e.g., the first layer 314a), is advantageous as the oxygen-rich BOₓ layers 314b, 314d provide better adhesion between the boron-based layer and the first dielectric layer 316 (FIG. 3C) to be formed on the oxygen-rich BOₓ layer (e.g., the second layer 314b) and between the boron-based layer and the dielectric material 301 (FIG. 3B) the oxygen-rich BOₓ layer (e.g., the third layer 314d) formed thereon.

FIG. 3B-4 illustrates a cross-sectional view of a first etch stop layer 314-4 in accordance some embodiments. The embodiment of FIG. 3B-4 is substantially identical to the embodiment shown in FIG. 3B-3 except that the third layer 314d is replaced by a third layer 314e. That is, the third layer 314e is disposed below and in contact with the first layer 314a. The third layer 314e may include the same material as the first layer 314a, however, the third layer 314e and the first layer 314a are selected so that they are chemically different from each other. In some embodiments, the first layer 314a may be BN or BC, the second layer 314b is an oxygen-rich BOₓ layer, and the third layer 314e may be BN or BC. In one exemplary embodiment, the first layer 314a is BN, the second layer 314b is an oxygen-rich BOₓ layer, and the third layer 314e is BC. In another exemplary embodiment, the first layer 314a is BC, the second layer 314b is an oxygen-rich BOₓ layer, and the third layer 314e is BN. In yet another exemplary embodiment, the first layer 314a is BN or BC, the second layer 314b is a BO having a first atomic percentage of oxygen, and the third layer 314e is an oxygen-rich BOₓ layer having a second atomic percentage of oxygen greater than the first atomic percentage of oxygen.

FIG. 3B-5 illustrates a cross-sectional view of a first etch stop layer 314-5 in accordance some embodiments. The embodiment of FIG. 3B-5 is substantially identical to the embodiment shown in FIG. 3B-4 except that the third layer 314e is replaced by a third layer 314f. That is, the third layer 314f is disposed below and in contact with the first layer 314a. In this embodiment, the third layer 314f is a boron-free layer, which may be formed of the material of the boron-free layer as discussed above with respect to FIG. 3B. In some embodiments, the first layer 314a may be BN or BC, the second layer 314b is an oxygen-rich BOₓ layer, and the third layer 314f may be SiN, SiCN, AlN, AlOₓ, SiON, SiOC, CN, or any combination thereof. In one exemplary embodiment, the first layer 314a is BN, the second layer 314b is an oxygen-rich BOₓ layer, and the third layer 314f is SiN and/or SiCN. In one exemplary embodiment, the first layer 314a is BC, the second layer 314b is an oxygen-rich BOₓ layer, and the third layer 314f is SiOC and/or SiON. In another exemplary embodiment, the first layer 314a is BC, the second layer 314b is an oxygen-rich BOₓ layer, and the third layer 314f is AlN and/or AlOₓ. In yet another exemplary embodiment, the first layer 314a is BN, the second layer 314b is an oxygen-rich BOₓ layer, and the third layer 314f is CN. In one yet another exemplary embodiment, the first layer 314a is a BO having a first atomic percentage of oxygen, the second layer 314b is an oxygen-rich BOₓ layer having a second atomic percentage of oxygen greater than the first atomic percentage of oxygen, and the third layer 314f is SiOC and/or SiON.

FIG. 3B-6 illustrates a cross-sectional view of a first etch stop layer 314-6 in accordance some embodiments. The embodiment of FIG. 3B-6 is substantially identical to the embodiment shown in FIG. 3B-5 except that the third layer 314f is not disposed below the first layer 314a. Instead, the third layer 314f is disposed above and in contact with the second layer 314b. In one exemplary embodiment, the first layer 314a is BN, the second layer 314b is an oxygen-rich BOₓ layer, and the third layer 314f is SiN and/or SiCN. In another exemplary embodiment, the first layer 314a is BC, the second layer 314b is an oxygen-rich BOₓ layer, and the third layer 314f is SiOC and/or SiON. In one another exemplary embodiment, the first layer 314a is BC, the second layer 314b is an oxygen-rich BOₓ layer, and the third layer 314f is AlN and/or AlOₓ. In yet another exemplary embodiment, the first layer 314a is BN, the second layer 314b is an oxygen-rich BOₓ layer, and the third layer 314f is CN. In one yet another embodiment, the first layer 314a is a BO having a first atomic percentage of oxygen, the second layer 314b is an oxygen-rich BOₓ layer having a second atomic percentage of oxygen greater than the first atomic percentage of oxygen, and the third layer 314f is SiOC and/or SiON.

In FIG. 3C, a first dielectric layer 316 is formed on the first etch stop layer 314. In some embodiments, the first dielectric layer 316 may be a low-k dielectric material, such as SiON, SiCN, SiOC, SiOCN, SiN, or any suitable low-k dielectric materials (e.g., a material having a dielectric constant lower than that of silicon dioxide). Alternatively, the first dielectric layer 316 may include the same material as the dielectric material 301 and may be formed by the same process as the dielectric material 301.

In FIG. 3D, a patterned mask layer 318 is formed over the first dielectric layer 316. The mask layer 318 may be any suitable masking material, such as a photoresist layer, a BARC (bottom anti-reflective coating) layer, a SOG (spin-on-glass) layer, or a SOC (spin-on-carbon) layer. In some embodiments, the mask layer 318 is a multi-layer resist, such as a tri-layer resist layer including a bottom layer, a middle layer formed over the bottom layer, and a photoresist layer formed over the middle layer. The bottom layer may be a bottom anti-reflective coating (BARC) layer and may include or be a carbon backbone polymer or a silicon-free material formed by a spin-on coating process, a CVD process, a FCVD process, or any suitable deposition technique. The middle layer may be a composition that provides anti-reflective properties and/or hard mask properties for a photolithography process. The middle layer provides etching selectivity from the bottom layer and the photoresist layer. The middle layer may include or be amorphous silicon, silicon carbide, silicon nitride, silicon oxynitride, silicon oxide, a silicon-containing inorganic polymer, or any combination thereof. The photoresist layer may include or be a DUV resist (KrF) resist, an argon fluoride (ArF) resist, an EUV resist, an electron beam (e-beam) resist, or an ion beam resist. Portions of the bottom layer, the middle layer, and the photoresist layer are then removed by a multi-step dry etch process to form patterned mask layer 318. The multi-step dry etch process may include a first etchant including CH₄, N₂, and O₂, a second etchant including CF₄, CHF₃, H₂, N₂, and Ar, and a third etchant including CF₄, O₂, and Ar. The dry etch process may be anisotropic, such as a reactive ion etch (RIE) process.

As a result of the multi-step dry etch process, openings 319 are formed in the mask layer 318, and a portion of first dielectric layer 316 is exposed. The exposed portion of the first dielectric layer 316 defines a contact region to be formed through the first dielectric layer 316 and the first etch stop layer 314 to the conductive feature 308. For ease of illustration, only one opening 319 is shown in FIG. 3C.

In FIG. 3E, the pattern (e.g., opening 319) of the mask layer 318 is transferred to the first dielectric layer 316 and the first etch stop layer 314, as shown in FIG. 3E. The transferring of the opening 319 forms an opening 317 extending through the first dielectric layer 316 and the first etch stop layer 314, and exposing a portion of the conductive feature 308. The transferring of the pattern may be performed by removing portions of the first dielectric layer 316 and the first etch stop layer 314 using one or more suitable etch processes, such as a dry etch, a wet etch, or a combination thereof. The opening 317 may be a via opening, in some embodiments. In some embodiments, the first dielectric layer 316 and the first etch stop layer 314 may be etched by a dry etch process with etch process gases including a form of fluorine, such as CHF₃, CF₄, CH₂F₂, C₂H₄F₂, SF₃, SF₆, the like, or a combination thereof. Additional process gasses may be used, such as Ar, H₂, N₂, O₂, and the like, or a combination thereof. In some embodiments where the first dielectric layer 316 includes oxides and the first etch stop layer 314 includes BN and BC, a multi-step dry etch process may be used. The multi-step dry etch process may include a first etchant including CF₄ and H₂, a second etchant including NF₃, H₂, N₂, and Ar, and a third etchant including NF₃, N₂, and Ar. An inert gas, such as N₂ or carbon dioxide (CO₂), may be provided between the first, second, and third etchants to flush out the etchant of the process chamber. The dry etch process may be anisotropic, such as a RIE process. In some embodiments, a post-treatment may be performed after the multi-step dry etch process to remove any etchant chemicals from the exposed surfaces of the interconnection structure 300. The post-treatment may use a nitrogen-containing plasma or a carbon containing plasma.

In FIG. 3F, a barrier layer 320 is deposited on exposed surfaces of the interconnection structure 300, such as the exposed surfaces of the mask layer 318, the first dielectric layer 316, the first etch stop layer 314, and conductive feature 308. A conductive feature 322 is then deposited over the barrier layer 320. The conductive feature 322 may serve as conductive vias (interconnect vias). The barrier layer 320 serves to prevent the metal diffusion from the conductive feature 322 to the first dielectric layer 316. The barrier layer 320 may include the same material as the barrier layer 310 and may be formed by a conformal process, such as ALD. The barrier layer 320 may have a thickness ranging from about 3 Angstrom to about 100 Angstroms, such as from about 5 Angstroms to about 50 Angstroms. The conductive feature 322 may be formed by filling a conductive material in the opening 317 (FIG. 3E) and followed by a planarization process, such as a CMP process. The conductive feature 322 may include any suitable conductive material, such as Cu, Ru, W, Ni, Al, Co, iridium (Ir), osmium (Os), gold (Au), palladium (Pd), platinum (Pt), silver (Ag), tantalum (Ta), titanium (Ti), or alloys thereof. The conductive feature 322 may be deposited using PVD, CVD, ALD, electroplating, ELD, or other suitable deposition process, or combinations thereof.

In FIG. 3G, a planarization process, such as a CMP process, is performed until a portion of the first dielectric layer 316 is exposed. In some embodiments, the planarization process is performed so that the top surfaces of the conductive feature 322, the first dielectric layer 316, and the barrier layer 320 are substantially co-planar.

In FIG. 3H, a second etch stop layer 324 is formed on the first dielectric layer 316, and a second dielectric layer 326 is formed on the second etch stop layer 324. In some embodiments, the second etch stop layer 324 is in contact with the top surfaces of the conductive feature 322, the first dielectric layer 316, and the barrier layer 320. The second etch stop layer 324 may include the same material as the first etch stop layer 314. The second dielectric layer 326 may include the same material as the first dielectric layer 316.

In FIG. 3I, openings 328 (only one is shown) are formed in the second dielectric layer 326 and the second etch stop layer 324 to expose portions of the first dielectric layer 316, the conductive features 322, and the barrier layer 320. The openings 328 may be formed by an etch process, such as a dry etch, wet etch, or a combination thereof. The openings 328 may be trench openings, in some embodiments.

In FIG. 3J, a barrier layer 330 is formed on exposed surfaces of the second dielectric layer 326, the second etch stop layer 324, the first dielectric layer 316, the barrier layer 320, and the conductive feature 322. A conductive feature 332 is then formed in the opening 328 (FIG. 3I). The conductive feature 332 may have a first dimension and the conductive feature 322 may have a second dimension less than the first dimension. Therefore, the conductive feature 332 may serve as conductive lines (interconnect lines). The barrier layer 330 may include the same material as the barrier layer 320. The conductive feature 332 may include the same material as the conductive feature 322 and may be formed using PVD, CVD, ALD, electroplating, ELD, or other suitable deposition process. Thereafter, a planarization process, such as a CMP process, is performed so that the top surfaces of the conductive feature 332, the barrier layer 330, and the second dielectric layer 326 are substantially co-planar. The conductive feature 332 and the conductive feature 322 form a single-damascene structure, which is in electrical contact with the conductive feature 308 (and thus the S/D features 124 or gate electrode layer 138, depending on the application).

While the conductive feature 332 and the conductive feature 322 are shown as a result of a single-damascene process, a dual-damascene process may be used to form the conductive features 322, 332. In such cases, the conductive feature 322 is in direct contact with the conductive feature 332 without the barrier layer 330 disposed between the conductive feature 322 and the conductive feature 332. In some embodiments, the barrier layer 320 between the conductive feature 322 and the conductive feature 308 may be removed so that the conductive feature 308 is in direct contact with the conductive feature 322.

Some embodiments relate to interconnection structures with an improved etch stop layer between IMD/ILD layer and a dielectric layer. The etch stop layer may be a multi-layer structure including a boron-based layer, an oxygen-rich BOₓ layer, a boron-free layer, or any combination thereof. The boron-based and boron-free layers enhance etch selectivity of the boron-based and boron-free layers with respect to the IMD/ILD layer, while the oxygen-rich BOₓ layer enhance adhesion between the IMD/ILD layer and the boron-based/boron-free layers. The improved etch stop layer may be used for dual-damascene or single damascene fabrication.

An embodiment is a method for forming an interconnection structure. The method includes forming a first conductive feature in a first dielectric material, forming an etch stop layer over the first dielectric material, which includes forming a boron-containing layer, and forming an oxygen-rich boron oxide layer on the boron-containing layer. The method also includes forming a second dielectric material over the etch stop layer, forming an opening through the second dielectric material and the etch stop layer to expose a top surface of the first conductive feature, and forming a second conductive feature in the opening.

Another embodiment is a method for forming an interconnection structure. The method includes forming a first conductive feature in a first dielectric material, forming a second conductive feature above the first conductive feature, and forming an etch stop layer over the first dielectric material and surround a portion of the second conductive feature, which includes forming a boron-containing layer, wherein the boron-containing layer has a first atomic percentage of oxygen, forming an oxygen-rich boron oxide layer on the boron-containing layer, wherein the oxygen-rich boron oxide layer has a second atomic percentage of oxygen greater than the first atomic percentage of oxygen, and forming a boron-free layer below the boron-containing layer.

Yet another embodiment is a method for forming an interconnection structure. The method includes forming a first conductive feature in a first dielectric material, forming a first etch stop layer over the first dielectric material which includes forming a boron-free layer, forming a boron-containing layer on the boron-free layer, and forming a boron oxide layer on the boron-containing layer. The method also includes forming a second dielectric material over the first etch stop layer, forming a via opening through the second dielectric material and the first etch stop layer to expose a top surface of the first conductive feature, forming a first barrier layer on exposed surfaces of the second dielectric material, the first etch stop layer, and the top surface of the first conductive feature, filling the via opening with a conductive material to form a second conductive feature, forming a second etch stop layer over the second dielectric material, wherein the second etch stop layer is substantially identical to the first etch stop layer, forming a third dielectric material over the second etch stop layer, forming a trench opening in the third dielectric material to expose top surfaces of the first barrier layer, the second conductive feature, and the second dielectric material, forming a second barrier layer on exposed surfaces of the third dielectric material, the second etch stop layer, the first etch stop layer, the second conductive feature, and the second dielectric material, and filling the trench opening with a conductive material to form a third conductive feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method for forming an interconnection structure, comprising:
forming a first conductive feature in a first dielectric material;
forming an etch stop layer over the first dielectric material, comprising:
forming a boron-containing layer; and
forming an oxygen-rich boron oxide layer on the boron-containing layer;
forming a second dielectric material over the etch stop layer;
forming an opening through the second dielectric material and the etch stop layer to expose a top surface of the first conductive feature; and
forming a second conductive feature in the opening.

2. The method of claim 1, further comprising:
forming a boron-free layer below and immediately adjacent to the oxygen-rich boron oxide layer.

3. The method of claim 2, wherein the boron-free layer is formed from a gas mixture using one or more of a silicon-containing precursor, a nitrogen-containing precursor, a carbon-containing precursor, and an oxygen-containing precursor.

4. The method of claim 2, wherein the boron-free layer is silicon nitride (SiN), silicon carbide (SiC), oxygen-doped silicon carbide (ODC), silicon carbon nitride (SiCN), silicon oxynitride (SiON), carbon nitride (CN), silicon oxide (SiOₓ), silicon carbon oxide (SiCO), aluminum nitride (AlN), aluminum oxide (AlOₓ), or the like, or any combination thereof.

5. The method of claim 1, wherein the boron-containing layer has a first atomic percentage of boron, and the oxygen-rich boron oxide has a second atomic percentage of boron that is greater than the first atomic percentage of boron.

6. The method of claim 1, wherein the boron-containing layer is boron nitride (BN), boron carbide (BC), boron carbon nitride (BCN), boron oxide (BO), silicon boron nitride (SiBN), or any combination thereof.

7. The method of claim 1, wherein the boron-containing layer is formed to have a first thickness and the oxygen-rich boron oxide layer is formed to have a second thickness, wherein the first thickness and the second thickness have a ratio (first thickness:second thickness) of about 1.5:1 to about 10:1.

8. The method of claim 1, wherein the boron-containing layer is formed at a deposition temperature lower than 550 degrees Celsius and a chamber pressure of about 0.5 Torr to about 10 Torr.

9. The method of claim 1, wherein the oxygen-rich boron oxide layer has an atomic percentage of oxygen in a range of about 50 at. % to about 80 at. %.

10. A method for forming an interconnection structure, comprising:
forming a first conductive feature in a first dielectric material;
forming a second conductive feature above the first conductive feature; and
forming an etch stop layer over the first dielectric material and surround a portion of the second conductive feature, comprising:
forming a boron-containing layer, wherein the boron-containing layer has a first atomic percentage of oxygen;
forming an oxygen-rich boron oxide layer on the boron-containing layer, wherein the oxygen-rich boron oxide layer has a second atomic percentage of oxygen greater than the first atomic percentage of oxygen; and
forming a boron-free layer below the boron-containing layer.

11. The method of claim 10, wherein the boron-containing layer or boron-free layer is formed to have a first thickness, and the oxygen-rich boron oxide layer is formed to have a second thickness that is less than the first thickness.

12. The method of claim 10, wherein the boron-free layer is SiN, SiCN, AlN, AlOₓ, SiON, SiOC, CN, or any combination thereof.

13. The method of claim 10, wherein the boron-containing layer is BO, and the boron-free layer is SiOC or SiON.

14. The method of claim 10, wherein the oxygen-rich boron oxide layer has an atomic percentage of oxygen in a range of about 50 at % to about 80 at %.

15. A method for forming an interconnection structure, comprising:
forming a first conductive feature in a first dielectric material;
forming a first etch stop layer over the first dielectric material, comprising:
forming a boron-free layer;
forming a boron-containing layer on the boron-free layer; and
forming a boron oxide layer on the boron-containing layer;
forming a second dielectric material over the first etch stop layer;
forming a via opening through the second dielectric material and the first etch stop layer to expose a top surface of the first conductive feature;
forming a first barrier layer on exposed surfaces of the second dielectric material, the first etch stop layer, and the top surface of the first conductive feature;
filling the via opening with a conductive material to form a second conductive feature;
forming a second etch stop layer over the second dielectric material, wherein the second etch stop layer is substantially identical to the first etch stop layer;
forming a third dielectric material over the second etch stop layer;
forming a trench opening in the third dielectric material to expose top surfaces of the first barrier layer, the second conductive feature, and the second dielectric material;
forming a second barrier layer on exposed surfaces of the third dielectric material, the second etch stop layer, the first etch stop layer, the second conductive feature, and the second dielectric material; and
filling the trench opening with a conductive material to form a third conductive feature.

16. The method of claim 15, wherein the boron-containing layer is boron oxide (BO) having an atomic percentage of boron in a range of about 15 at. % to about 45 at. %.

17. The method of claim 16, wherein the boron oxide layer has an atomic percentage of boron in a range of about 20 at. % to about 50 at. %.

18. The method of claim 15, wherein the boron-free layer is silicon nitride (SiN), silicon carbide (SiC), oxygen-doped silicon carbide (ODC), silicon carbon nitride (SiCN), silicon oxynitride (SiON), carbon nitride (CN), silicon oxide (SiOₓ), silicon carbon oxide (SiCO), aluminum nitride (AlN), aluminum oxide (AlOₓ), or the like, or any combination thereof.

19. The method of claim 15, wherein the boron-containing layer is a doped and has a hardness higher than 10 GPa.

20. The method of claim 15, wherein the boron-containing layer is boron nitride (BN), boron carbide (BC), boron carbon nitride (BCN), boron oxide (BO), silicon boron nitride (SiBN), or any combination thereof.
